(19) United States
(12) Patent Application Publication
(10) Pub. No.: US 2007/0023879 A1
(43) Pub. Date: Feb. 1, 2007

(54) Single unit heat sink, voltage regulator, and package solution for an integrated circuit

(76) Inventors: Vinayak Pandey, Chandler, AZ (US); Pramod Malatkar, Chandler, AZ (US); Sundarshan V. Rangaraj, Chandler, AZ (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/192,504

(22) Filed: Jul. 29, 2005

(51) Int. Cl. H01L 23/02

(52) U.S. Cl. 257/678

(57) ABSTRACT

A method, apparatus, and system with a subassembly for simple integration of high power integrated electronics, the subassembly including an integrated circuit package, an integrated circuit package cooling device and a printed circuit board with coupled power delivery components.

### TECHNICAL FIELD

The invention relates to the field of microelectronics and more particularly, but not exclusively, to package, power delivery, and thermal ingredient integration.

### BACKGROUND

The evolution of integrated circuit designs has resulted in higher operating frequency, increased numbers of transistors, and physically smaller devices. This continuing trend has generated ever increasing area densities of integrated circuits and packing densities of integrated circuit assemblies. To date, this trend has resulted in both increasing power and increasing heat flux devices, and the trend is expected to continue into the foreseeable future.

Reductions in operating voltage have slowed the trend to higher power and higher heat flux microelectronic devices. However, reducing operating voltage demands tighter control over variations in voltage, despite commonly operating with transient, high current operation. A change in voltage, V, under a current, i, varying with time may partially derive from electrical inductance, l, according to

$$υ = ℓ \frac{ⅆ i}{ⅆ t} ,$$

where

$$\frac{ⅆ i}{ⅆ t}$$

describes the time variation of current, i. A common method of reducing electrical inductance may involve reducing the number of electrical discontinuities (e.g., connectors). Another may involve reducing the distance over which the current travels from power source to integrated circuit die.

Although reducing operating voltage may reduce power consumption, the trend to higher power and higher heat flux components continues. Thus, continual improvement in cooling technologies is required. Further, integrated circuit components other than the processor (e.g., power delivery components, graphics components, memory components, chipset components) require continually evolving thermal solutions.

System integrators demand components seamlessly and easily integrate to manage system assembly costs. Thus, delivery of complex, multipart mechanical solutions requiring system integrators to create sub-assemblies prior to system integration does not deliver an optimal solution. However, in the past, simple mechanical solutions and competing technology requirements (e.g., power delivery requirements drive components close together, thermal requirements drive components apart) could be accommodated by well thought printed circuit board (e.g., motherboard, baseboard) design.

### BRIEF DESCRIPTION OF THE DRAWINGS

FIG. 1 illustrates an exploded assembly view of an embodiment of a compact integration unit, showing detail of several components to the embodiment.

FIG. 2 illustrates a side view of an embodiment of a compact integration unit after assembly.

FIG. 3 illustrates an inverted, perspective view of an embodiment of a compact integration unit after assembly, showing detail of several components to the embodiment.

FIG. 4 illustrates an electrical connector, a component to an embodiment of a compact integration unit mechanically, structurally, and electrically coupled to a printed circuit board.

FIG. 5 illustrates a mechanical clip, a component to an embodiment of a compact integration unit.

FIG. 6 illustrates a mechanical clip mated to an electrical connector, a subassembly of an embodiment of a compact integration unit mechanically, structurally, and electrically coupled to a printed circuit board.

FIG. 7 illustrates a board level assembly of an embodiment of a compact integration unit mechanically, structurally, and electrically coupled to a printed circuit board.

FIG. 8 illustrates a system schematic incorporating an embodiment of a compact integration unit mechanically, structurally, and electrically coupled to a printed circuit board.

FIG. 9 illustrates results of a numerical analysis, the numerical analysis simulating out of plane displacement of a package substrate of an embodiment of a compact integration unit.

FIG. 10 illustrates results of a numerical analysis, the numerical analysis simulating out of plane displacement of a mechanical clip and package substrate of an embodiment of a compact integration unit.

FIG. 11 illustrates an embodiment of a method of forming a Compact Integration Unit and coupling the Compact Integration Unit to a motherboard or baseboard.

### DETAILED DESCRIPTION

Herein disclosed are a method, apparatus, and system for providing and using a compact integration of a package containing an integrated circuit, a printed circuit board (or substrate) with power delivery components, and one or more heatsinks, the compact integration (hereinafter “Compact Integration Unit” or “CIU”) able to be mechanically, thermally, and electrically coupled to a motherboard (or alternatively, in a server, a baseboard). In the following detailed description, reference is made to the accompanying drawings which form a part hereof wherein like numerals designate like parts throughout, and in which is shown by way of illustration specific embodiments in which the invention may be practiced. It is to be understood that other embodiments may be utilized and structural or logical changes may be made without departing from the intended scope of the embodiments presented. It should also be noted that directions and references (e.g., up, down, top, bottom, primary side, backside, etc.) may be used to facilitate the discussion of the drawings and are not intended to restrict the application of the embodiments of this invention. Therefore, the following detailed description is not to be taken in a limiting sense and the scope of the embodiments of the present invention is defined by the appended claims and their equivalents.

### Compact Integration Unit Assembly

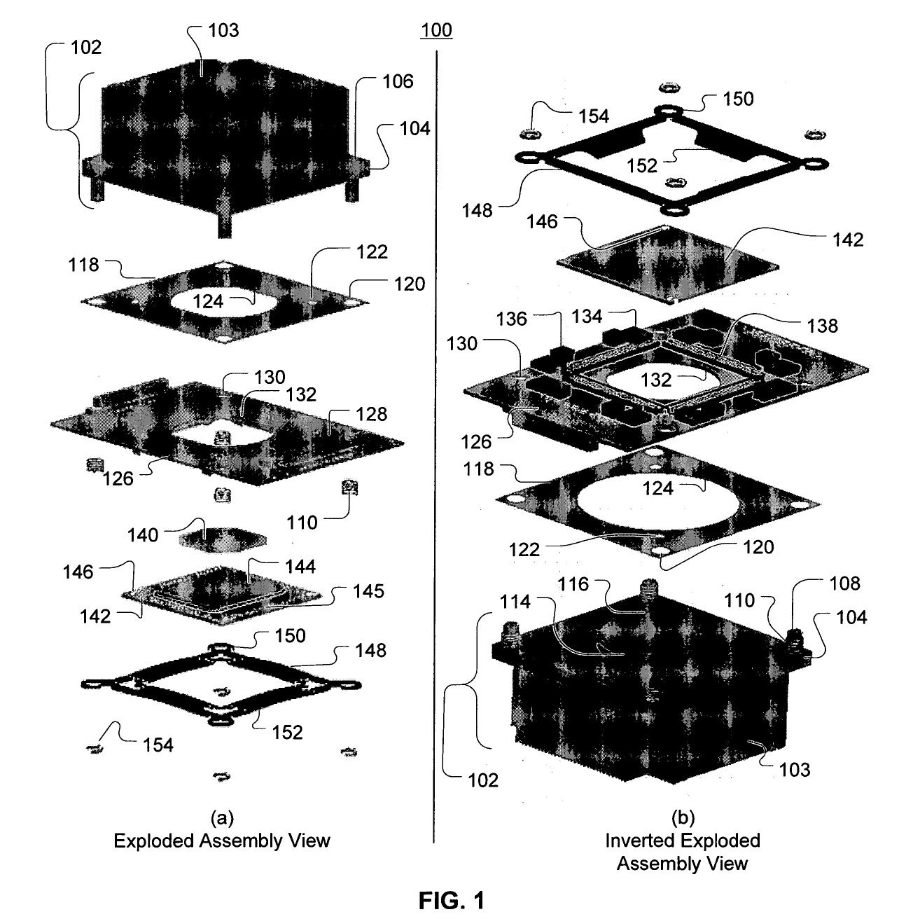

FIG. 1 illustrates an exploded assembly view of an embodiment of a Compact Integration Unit 100, showing detail of several components to the embodiment. The depiction of FIG. 1 includes a stack of several adjoining components: a heat sink 102 separated from a printed circuit board with voltage regulation components 126 by a first layer of thermal interface material 118, the heat sink 102 also separated from a package containing an integrated circuit 145 by a second layer of thermal interface material 140, and a retention clip 148 secured to the heat sink 102 applying a compressive load to the stack of several adjoining components.

The heat sink 102 depicted by FIG. 1 may include a plurality of fins 103 adjoining a base 104. The bulk material forming the fins 103 may be continuous with the bulk material forming the base 104, such as with a heat sink machined from a single block of material, a heat sink formed by a traditional extrusion process, a forging process, or an impact extrusion type process. Alternatively, the material forming the fins 103 may simply be adjoining the material forming the base 104, such as in a folded fin heat sink, where the plurality of fins 103 are formed by corrugating a sheet of material and are soldered, epoxied, or otherwise thermally coupled to the base 104. Yet another alternative arrangement for the plurality of fins 103 may be plates embedded or swaged into a base 104. Still another alternative for the geometry of each in the plurality of fins may be pin fins, triangular fins, oval fins, staggered pins, and so forth.

The heat sink base 104 depicted in FIG. 1 may be formed by a continuous bulk material, such as a heat sink 102 formed by a machining process, extrusion process, forging process, swaging process, or impact extrusion process. Alternatively, the heat sink base 104 may be formed by a planar heat pipe, vapor chamber heat pipe, or a combination of a plate of continuous bulk material with heat pipes embedded in the base 104. Yet another alternative embodiment of the heat sink base 104 could be a liquid cooled heat exchanger.

The heat sink base 104 may also form features able to thermally, mechanically, and/or electrically couple to a package 145, the package 145 containing an integrated circuit, and/or a printed circuit board (“PCB”) 126 with voltage regulation (“VR”) components 134 and 136. An embodiment of a heat sink base 104 feature able to mechanically couple or align a package 145 and/or a PCB 126 with mounted VR components 134 and 136 may be a post 108. In one embodiment, a post 108 may be formed of the continuous bulk material forming the heat sink base 104. In another embodiment, a post 108 may be swaged into a hole 106 formed in the heat sink base 104. An alternative heat sink base feature able to mechanically couple or align a package 145 and/or a PCB 126 may be a notch 116 in the heat sink base 104.

One embodiment of a heat sink base 104 feature which may be able to thermally couple to a package containing an integrated circuit 145 is shown in FIG. 1(b) as a “step region” 114, the step region 114 being an area roughly parallel, but offset, to the plane formed by the heat sink base 104. Alternatively, the step region 114 may form a recess in the heat sink base 104. The step region 114 may be formed, or machined, to be substantially flat, making it able to thermally couple to a package 145, or an integrated heat spreader (“IHS”) 144 covering an integrated circuit die mounted to a package 145. Yet another alternative embodiment of a heat sink base 104 may be able to thermally couple to both a package 145 and a PCB 126. An embodiment, as shown in FIG. 1(b), may thermally couple to both a package 145 and a PCB 126. The step region 114 may thermally couple to a package and a region 112 of the heat sink base 104 may thermally couple to a PCB 126. Heat transfer through the thermally coupled step region 114 may be enhanced through use of a first thermal interface material 140 and heat transfer through the region 112 thermally coupled to the PCB 126 may be enhanced through use of a second thermal interface material 118.

A wide range of embodiments of thermal interface materials 140 and 118 may be employed. For example, one embodiment may include silicon grease with thermally conductive filler material. Another embodiment may include a thermally conductive but mechanically compliant pad-like material. Yet another embodiment may include a thermally conductive phase change material. One embodiment of a thermally conductive phase change material may include a paraffin-like wax with thermally conductive filler material. Another embodiment of a thermally conductive phase change material may include a low melting temperature metal alloy.

An embodiment of a thermal interface material 140 or 118 may include features for alignment 120 and 122. A feature for alignment 122 may accept a feature 108 adjoining a heat sink base 104. In one embodiment, the feature for alignment 122 may be a hole and the heat sink base 104 feature may be a post 108. Further, a thermal interface material 118 able to enhance the thermal coupling between a heat sink base 104 and a PCB 126 may form a region 124 through which an IHS 144 may pass.

Further, a heat sink base 104 may include features to electrically couple the heat sink to a PCB 126 and/or a package 145. A heat sink electrically coupled to a PCB 126 and/or a package 145 may act as a partial Faraday cage and may suppress electromagnetic interference (“EMI”) emissions associated with a high frequency electrical signal commonly present in integrated electronic devices and integrated circuits, like a microprocessor.

The package 145 may further form features able to thermally, mechanically and/or electrically couple to a heat sink. One embodiment of a package 145 may have an IHS 144 able to thermally couple to a heat sink. An alternative embodiment of a package 145 may form a hole 146 within a substrate 142 able to mechanically couple and align the package 145 to a heat sink base 104. Yet another embodiment of a package substrate 142 may form a region to electrically couple to a heat sink.

Further, the package 145 may form features to electrically couple the package 145 to a connector 138 mounted to a PCB 126 with voltage regulation components 134 and 136. Another embodiment of the package substrate 142 may contain an array of electrical connections on a side opposite an IHS 144 (e.g., see FIG. 1(b)), the array of electrical connections able to electrically couple the substrate 142 to an electrical connector mounted on a motherboard (not shown). In yet another embodiment, an array of electrical connections to either, or both, the PCB 126 and motherboard (not shown) may be formed to electrically couple to a land grid array (LGA) socket.

An embodiment of the PCB 126 may form a hole 132 through which a package 145 may pass. Another embodiment of the PCB 126 may form an alignment feature 130. In one embodiment, the alignment feature 130 may be a hole through which an alignment feature 108 adjoining a heat sink base 104 may pass. Further, an embodiment of the PCB 126 may incorporate a connector 128 (see e.g., FIG. 1(a)) for electrically coupling the PCB 126 to a power supply (not shown). Yet another embodiment of the PCB 126 may incorporate VR components 136 and 134 (e.g., FIG. 1(b)). In still another embodiment, the VR components 136 and 134 may include Field Effect Transistors (“FETs”) and/or inductors.

One embodiment of a Compact Integration Unit 100 may utilize a clip 148 to apply a compressive load to a stack including one or more of the following: a package 145, a first thermal interface material 140, a PCB 126, a second thermal interface material 118 and a heat sink base 104. One embodiment of a clip 148 may include a feature 150 to interface to a heat sink feature 108. Further, an embodiment of a clip 148 may incorporate a flange 152 through which a compressive load is applied to a package substrate 146. Another embodiment of the CIU 100 may include a device 110 to apply a compressive load directly to the PCB 126. One embodiment of the device 110 that applies a compressive load directly to the PCB 126 may be a bushing surrounding a post 108 coupled to the heat sink base 104. Another embodiment of the device 110 may be a spring. An embodiment of the CIU may further incorporate a washer 154 swaged to the post 108 of the heat sink base 104, the clip 148 retained in place by a washer 154 or a group of washers 154. Another embodiment of the CIU may replace the washer 154 and post 108 with a bolt threaded into a hole 106. In still another embodiment, the washer 154 may be replaced by a screw threaded into the post 108, the cap of the screw retaining the clip 148.

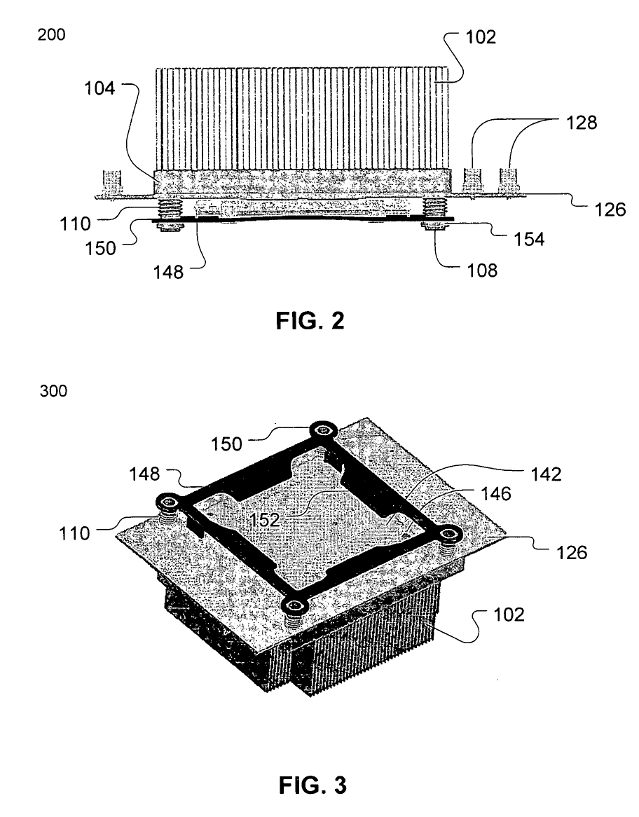

FIG. 2 illustrates a side view of an embodiment of a CIU after assembly and FIG. 3 illustrates an inverted, perspective view of an embodiment of a CIU after assembly, showing detail of several components to the embodiment.

### An Embodiment of a Compact Integration Unit Coupled to a Motherboard

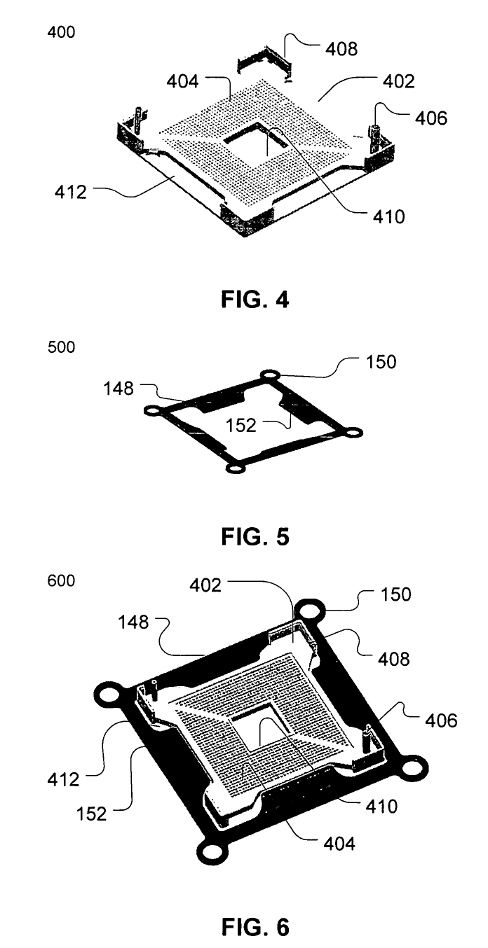

FIG. 4 illustrates an embodiment of an electrical connector 402, a component to an embodiment of a compact integration unit mechanically, structurally, and electrically coupled to a motherboard. One embodiment of an electrical connector 402 may incorporate one or more features 406, 408, and 412 for mechanically coupling a CIU to a printed circuit board. An embodiment of a mechanical coupling feature may be one or more of a post 406 passing through a hole formed in a package substrate, a recess 412 to accommodate a flange (see e.g., 152 of FIG. 5) on a retention clip, and a chamfered wall 408 to align a package substrate. Further, an embodiment of an electrical connector 402 may define a hole 410 or a recess. The hole 410 or recess may accommodate electrical devices on a land side of a package substrate.

FIG. 5 illustrates an embodiment of a mechanical clip, a component to an embodiment of a compact integration unit, previously discussed.

FIG. 6 illustrates an embodiment of a retention clip 148 mated to an embodiment of an electrical connector 402, a subassembly of an embodiment of a compact integration unit mechanically, structurally, and electrically coupled to a printed circuit board.

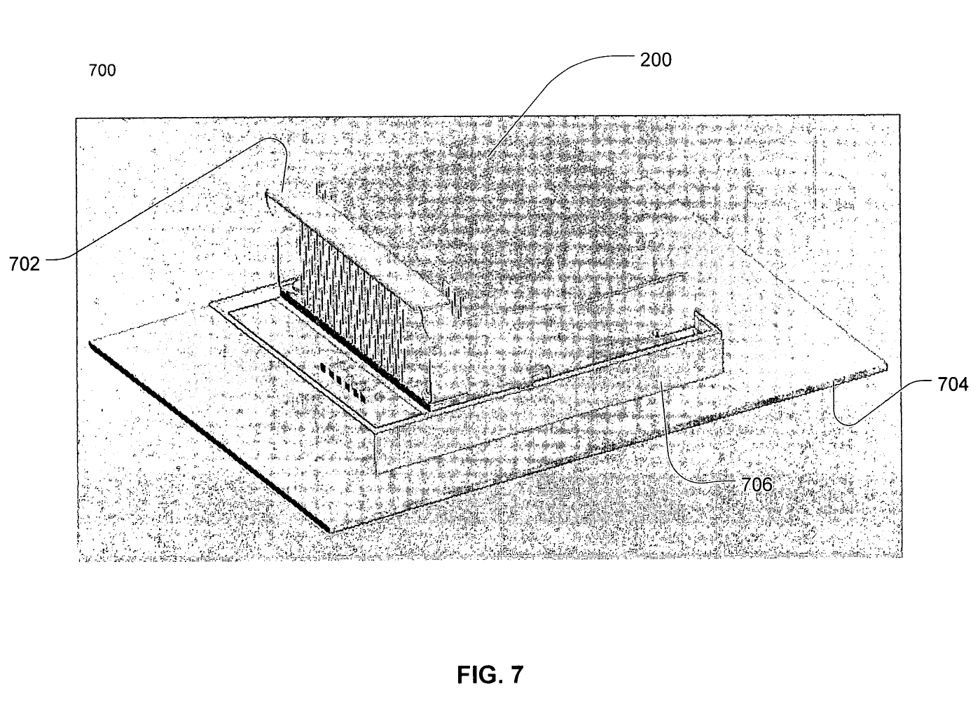

FIG. 7 illustrates a board level assembly of an embodiment of a compact integration unit 200 mechanically, structurally, and electrically coupled to a printed circuit board 704. An embodiment of an electrical connector 706 may electrically couple a PCB containing VR components to a motherboard or other PCB 704. The CIU 200 may be mechanically coupled to an electrical connector by way of a retention mechanism 702.

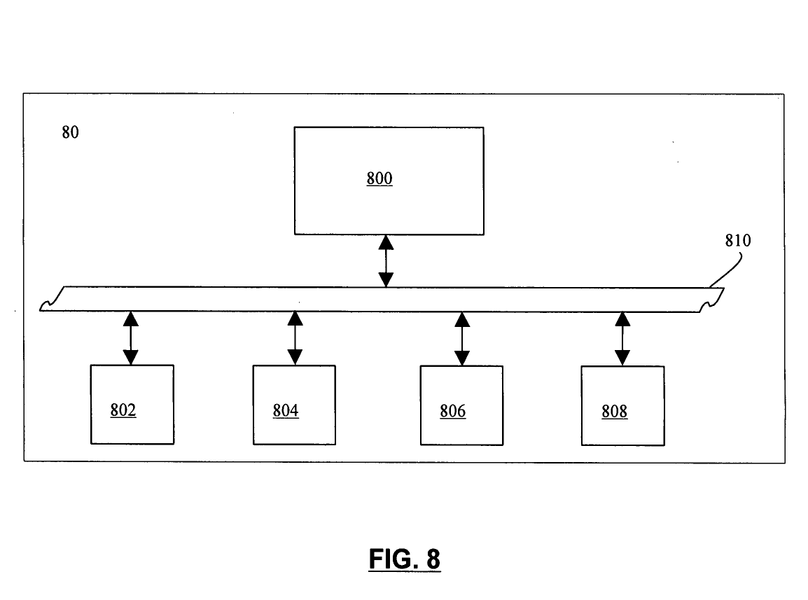

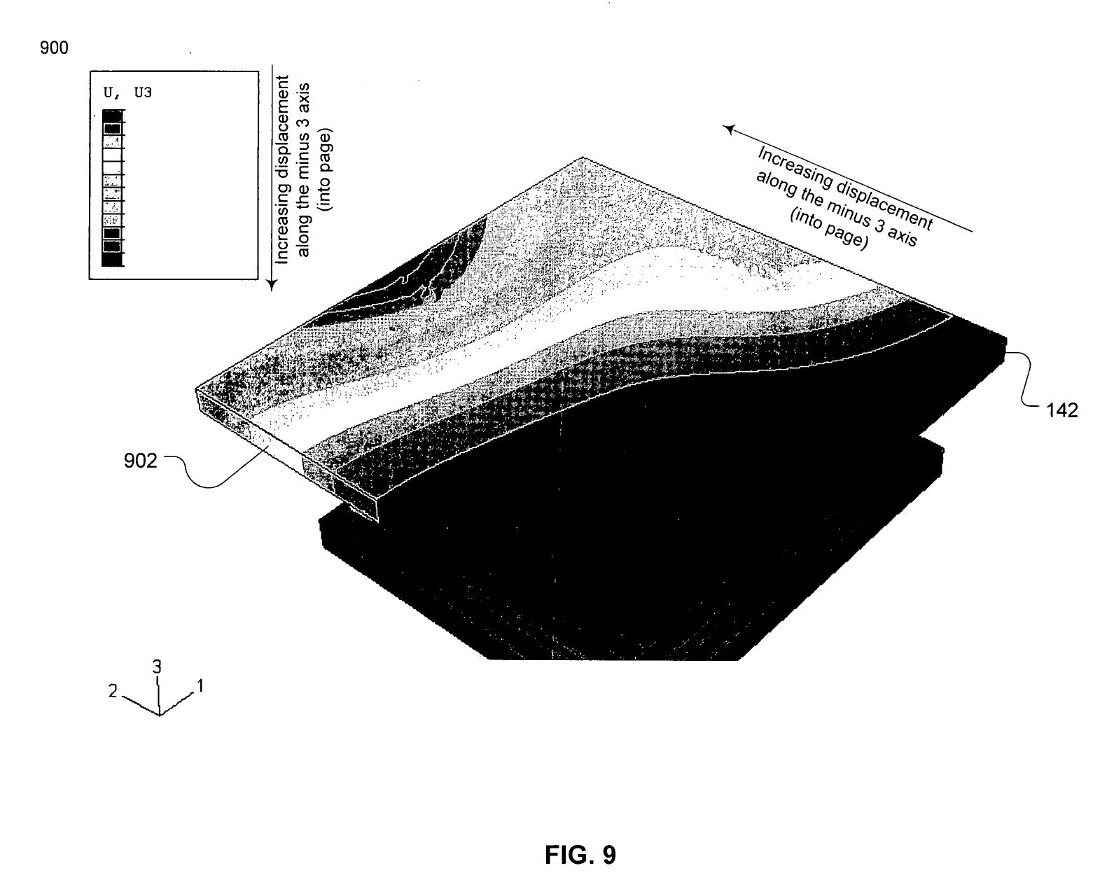

FIG. 8 illustrates a schematic representation of one of many possible system embodiments. The CIU assembly 800 may include a subassembly similar to each subassembly 100, 200, 300, 600, and 700 depicted in FIG. 1-FIG. 3 and FIG. 6-FIG. 7, respectively. Further, the CIU assembly 800 may include a component similar to each component 400 and 500 depicted in FIG. 4 and FIG. 5, respectively. In one embodiment, the CIU assembly 800 may include a package containing an integrated circuit. In another embodiment, the integrated circuit may include a microprocessor. In an alternate embodiment, the integrated circuit package may include an application specific IC (ASIC). Integrated circuits found in chipsets (e.g., graphics, sound, and control chipsets) or memory may also be packaged in accordance with embodiments of this invention.

For an embodiment similar to the embodiment depicted in FIG. 8, the system 80 may also include a main memory 802, a graphics processor 804, a mass storage device 806, and an input/output module 808 coupled to each other by way of a bus 810, as shown. Examples of the memory 802 include but are not limited to static random access memory (SRAM) and dynamic random access memory (DRAM). Examples of the mass storage device 806 include but are not limited to a hard disk drive, a flash drive, a compact disk drive (CD), a digital versatile disk drive (DVD), and so forth. Examples of the input/output modules 808 include but are not limited to a keyboard, cursor control devices, a display, a network interface, and so forth. Examples of the bus 810 include but are not limited to a peripheral control interface (PCI) bus, PCI Express bus, Industry Standard Architecture (ISA) bus, and so forth. In various embodiments, the system 80 may be a wireless mobile phone, a personal digital assistant, a pocket PC, a tablet PC, a notebook PC, a desktop computer, a set-top box, an audio/video controller, a DVD player, a network router, a network switching device, or a server.

FIG. 9 illustrates results 902 from a numerical simulation of out of plane (along the axis labeled “3”) displacement of an embodiment of a CIU including a package substrate 142 under a compressive mechanical load representative of a load maintaining reliable thermal interfaces. The data of FIG. 9 shows acceptably small out of plane substrate displacement compared to typical allowable out of plane substrate displacement when using an embodiment of an LGA socket similar to the LGA socket 400 shown in FIG. 4.

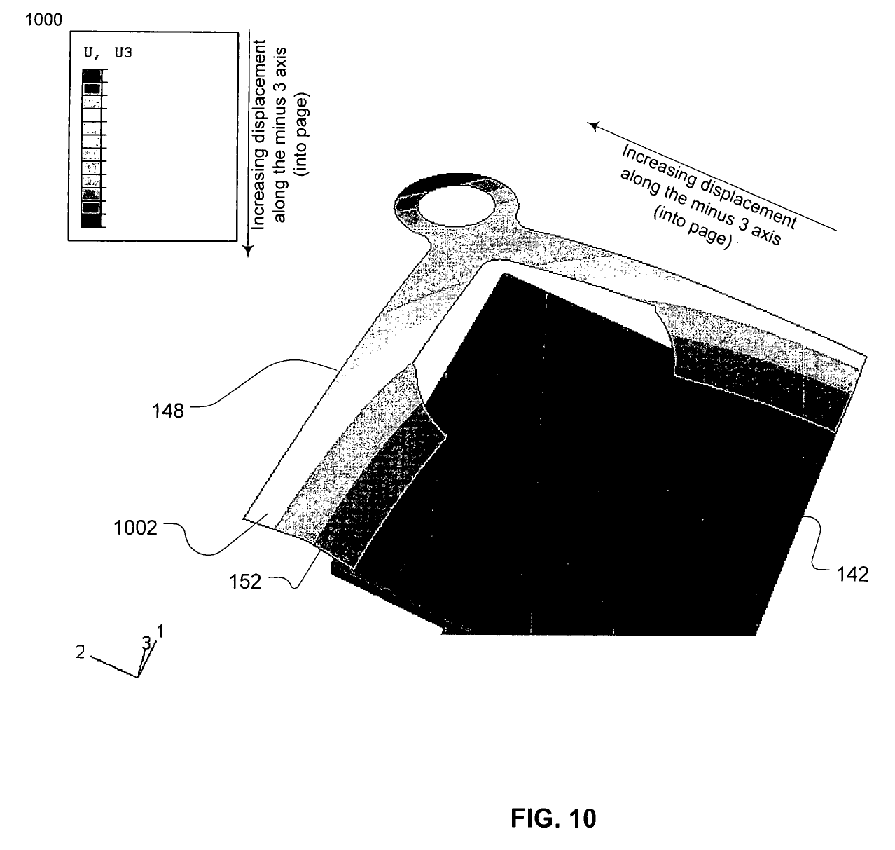

FIG. 10 illustrates results 1002 from further numerical simulation of out of plane (along the axis labeled “3”) displacement of an embodiment of a CIU including a package substrate 142 and clip 148 under a compressive mechanical load applied at an alignment and fastening area 150 of the clip 148 and transferred to the package substrate 142 through a flange 152 on the clip 148. The resulting compressive load modeled is representative of a load maintaining reliable thermal interfaces. The data of FIG. 10 shows acceptably small out of plane substrate displacement compared to typical allowable out of plane substrate displacement when using an embodiment of an LGA socket similar to the LGA socket 400 shown in FIG. 4. Further, the data of FIG. 10 shows displacement of the clip at the alignment and fastening area 150 consistent with elastic, as opposed to plastic, deformation of the clip. In an alternative embodiment, some plastic deformation of the clip 148 may occur.

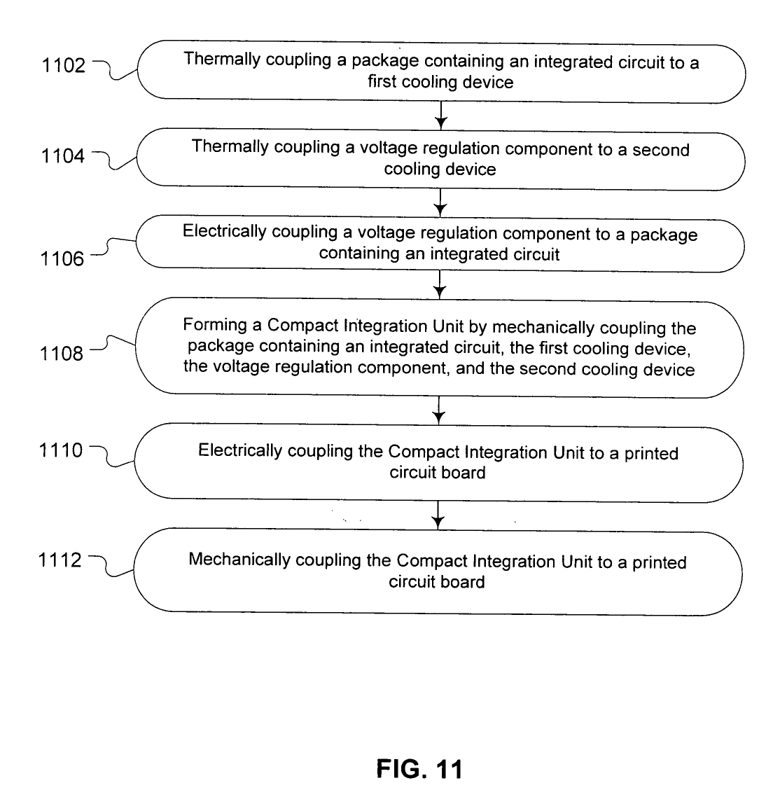

FIG. 11 illustrates one embodiment of a method of forming a Compact Integration Unit and coupling the Compact Integration Unit to a baseboard, motherboard, or other printed circuit board 1110 and 1112, the CIU forming a subsystem assembly coupled to a bus, baseboard, motherboard or other printed circuit board containing a bus, the bus connecting other integrated circuit subsystems. Forming a Compact Integration Unit may include thermally coupling a first cooling device to a package containing an integrated circuit 1102, thermally coupling a second cooling device to a voltage regulation component 1104, electrically coupling voltage regulation component to a package containing an integrated circuit 1106, mechanically coupling the first cooling device, the package containing an integrated circuit, the second cooling device, and the voltage regulation component 1108.

Although specific embodiments have been illustrated and described herein for purposes of description of an embodiment, it will be appreciated by those of ordinary skill in the art that a wide variety of alternate and/or equivalent implementations calculated to achieve similar purposes may be substituted for the specific embodiments shown and described without departing from the scope of the present disclosure. For example, an alternative embodiment may exist where VR component packaging integrates a cooling solution. Another embodiment may couple a first heat sink (or other thermal solution) to a package containing an integrated circuit including a microprocessor and a second heat sink (or other thermal solution) to a VR component. Yet another embodiment may exist wherein the CIU assembly includes an integrated retention mechanism to interface with features on a motherboard. Those with skill in the art will readily appreciate that the present invention may be implemented using a very wide variety of embodiments. This detailed description is intended to cover any adaptations or variations of the embodiments discussed herein. Therefore, it is manifestly intended that this invention be limited only by the claims and the equivalents thereof.

1. An apparatus comprising:
a package containing an integrated circuit;
power delivery components electrically and mechanically coupled to a printed circuit board, adjoining the package, wherein the printed circuit board and the package are electrically coupled;
an integrated circuit package cooling device thermally coupled to the package and mechanically coupled to the package and printed circuit board, wherein the cooling device includes protruding studs integral to the cooling device; and
a substantially planar retention clip coupled to the studs, wherein the clip has a plurality of prongs that bear on the package so as to cause the printed circuit board and the package to be in compression between the clip and the cooling device.

2. The apparatus of claim 1, wherein the printed circuit board and the package are electrically coupled by a separable electrical connector.

3. The apparatus of claim 1, wherein the integrated circuit comprises a microprocessor.

4. The apparatus of claim 1, wherein the integrated circuit package cooling device comprises one chosen from a group consisting of a heat sink, cold plate, refrigeration system, liquid cooling system, and a combination thereof.

5. The apparatus of claim 1, wherein the integrated circuit package cooling device is thermally coupled to the power delivery components.

6. The apparatus of claim 5, wherein the thermal coupling between the integrated circuit package cooling device and the power delivery components comprises a thermally conductive, compliant pad.

7. The apparatus of claim 1, wherein the printed circuit board electrically coupled to the package forms a void through which a portion of the package passes, the portion of the package thermally coupled to the integrated circuit cooling device.

8. The apparatus of claim 1, wherein the subassembly capable of further coupling to a second printed circuit board may be coupled to the second printed circuit board by way of a land grid array (“LGA”) socket.

9. A method comprising:
electrically coupling a package containing an integrated circuit and a printed circuit board coupled to power delivery components;
thermally coupling the package containing an integrated circuit and an integrated circuit package cooling device;
mechanically coupling the package containing an integrated circuit and the printed circuit board with coupled power delivery components in compression between the integrated circuit package cooling device and a clip, wherein the clip is substantially planar and has a first set of features capable of mechanically coupling to one or more integral studs that protrude from the cooling device and a second set of features capable of bearing on the package; and
forming a subassembly capable of further coupling to a second printed circuit board.

10. The method of claim 9, wherein the integrated circuit comprises a microprocessor.

11. The method of claim 9, wherein the integrated circuit package cooling device comprises one chosen from a group consisting of a heat sink, cold plate, refrigeration system, liquid cooling system, and a combination thereof

12. The method of claim 9, further comprising thermally coupling the power delivery components to the integrated circuit package cooling device.

13. The method of claim 12, wherein thermally coupling between the integrated circuit package cooling device and the VR components comprises using a thermally conductive, compliant pad

14. The method of claim 9, further comprising the printed circuit board electrically coupled to the package forming a void through which a portion of the package passes, the portion of the package thermally coupled to the integrated circuit cooling device.

15. The method of claim 9, further comprising integrating a land grid array (“LGA”) socket in the subassembly capable of further coupling to a second printed circuit board.

16. The method of claim 9, further comprising compressing the mechanically coupled heat sink, printed circuit board with coupled VR components, and package between a clip and the integrated circuit package cooling device.

17. A system comprising:
a package containing an integrated circuit;
power delivery components electrically coupled to a printed circuit board, the printed circuit board electrically coupled to the package;
an integrated circuit package cooling device with integral protruding studs thermally coupled to the package and mechanically coupled to the package and printed circuit board by a substantially planar clip mechanically coupled to the protruding studs, wherein the clip, when attached to the studs, places the package and printed circuit board in compression between the clip and the cooling device wherein
the mechanically coupled cooling device, printed circuit board, and package form a subassembly capable of further coupling to a second printed circuit board; and
a mass storage device coupled to the subassembly capable of further coupling to a second printed circuit board.

18. The system of claim 17, further comprising:
a dynamic random access memory coupled to the integrated circuit; and
an input/output interface coupled to the integrated circuit.

19. The system of claim 18, wherein the input/output interface comprises a networking interface.

20. The system of claim 17, wherein the integrated circuit is a processor.

21. The system of claim 20, wherein the system is a selected one of a group comprising a set-top box, a media-center personal computer, a digital versatile disk player, a server, a personal computer, a mobile personal computer, a network router, and a network switching device.

22. An apparatus comprising:
a package containing an integrated circuit;
power delivery components electrically coupled to a printed circuit board, the printed circuit board electrically coupled to the package;
an integrated circuit package cooling device thermally coupled to the package and mechanically coupled to the package and printed circuit board, wherein the cooling device includes a plurality of protruding studs; and
a substantially planar retention clip with a first plurality of features capable of mating with the studs of the cooling device and a second plurality of features capable of mating with the package, wherein the retention clip mechanically couples the printed circuit board and the package in compression between the clip and the cooling device, and thereby, forms a subassembly.
